(19) United States
(12) Patent Application Publication
(10) Pub. No.: US 2008/0194098 A1
(43) Pub. Date: Aug. 14, 2008

(54) FLASH MEMORY DEVICE AND METHOD OF MANUFACTURING THE SAME

(75) Inventor: Yong Chul Shin, Cheongju-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/771,989

(22) Filed: Jun. 29, 2007

(30) Foreign Application Priority Data
Feb. 9, 2007 (KR) 10-2007-13674

(51) Int. Cl. H01L 21/4763; H01L 29/788

(52) U.S. Cl. 438/637; 257/316; 257/E29.3; 257/E21.495

(57) ABSTRACT

A method of forming a semiconductor device includes forming a first conductive layer over a semiconductor substrate. A dielectric layer is formed over the first conductive layer. A mask pattern having a first opening is formed over the dielectric layer. The mask pattern is annealed to convert the first opening into a second opening that is smaller than the first opening. The dielectric layer is etched using the mask pattern with the second opening to form a hole that exposes the first conductive layer. A second conductive layer is formed over the dielectric layer and within the hole, the second conductive layer contacting the first conductive layer pattern through the hole.

### CROSS-REFERENCES TO RELATED APPLICATIONS

The present application claims priority to Korean patent application number 10-2007-013674, filed on Feb. 9, 2007, which is incorporated by reference in its entirety.

### BACKGROUND OF THE INVENTION

The present invention relates to a semiconductor device and, more particularly, to a manufacturing method of forming a dielectric layer contact hole, in which the size of the dielectric layer contact hole can be reduced.

A semiconductor flash memory device includes a plurality of memory cells and select transistors. The select transistor is formed at both ends of a string comprising a plurality of memory cells. This structure is repeated to form a NAND flash memory device.

The memory cell stores electrons by trapping electrons in the floating gate. A dielectric layer is formed between a floating gate and a control gate, so that the floating gate and the control gate are electrically isolated from each other. The flash memory cell has a structure in which a tunnel insulating layer, a first conductive layer for a floating gate, a dielectric layer and a second conductive layer for a control gate are stacked on a semiconductor substrate.

The select transistor includes a first conductive layer for the floating gate, but a line-shaped hole is formed in the dielectric layer because it must operate like a general transistor so that an electrical path is formed between a first conductive layer for the floating gate and a second conductive layer for the control gate. The hole formed in the dielectric layer is referred to as a “dielectric layer contact hole.” The size of the dielectric layer contact hole is preferably smaller than a width of a select line, which is formed as the gates of a select transistor are connected.

As devices shrink and the degree of integration of semiconductor devices gradually increases, the size of the dielectric layer contact hole must also shrink. If the size of the dielectric layer contact hole is not made smaller, device failure may occur since regions other than the select transistor region may be etched. Thus, in order to form a fine pattern by reducing the size of the dielectric layer contact hole, exposure equipment with high resolution must be used. However, this requires expensive equipment, resulting in an increased manufacturing cost.

### SUMMARY OF THE INVENTION

Accordingly, the present invention relates to a method of forming a dielectric layer contact hole of a semiconductor device, in which the dielectric layer contact hole for connecting the floating gate and the control gate is formed in a hole type not a line type, and where a photoresist pattern for defining the dielectric layer contact hole is formed and then resist-reflowed by an annealing process, so that the dielectric layer contact hole having a small size can be formed without using expensive exposure equipment.

In an aspect, the present invention provides a method of forming a flash memory device, including the steps of forming a first conductive layer pattern and an isolation layer over a semiconductor substrate, forming a dielectric layer on the isolation layer and the first conductive layer, forming a photoresist pattern having first aperture units on the dielectric layer, performing an annealing process to form second aperture units having a size smaller than that of the first aperture units of the photoresist pattern, patterning the dielectric layer along the photoresist pattern, thus forming dielectric layer contact holes, removing the photoresist pattern, and forming a second conductive layer on the dielectric layer and the first conductive layer.

In another aspect, the present invention provides a flash memory device, including an isolation layer formed in an isolation region of a semiconductor substrate, a plurality of word lines and select lines formed on the semiconductor substrate and crossing the isolation layer, each of the plurality of word lines and select lines including a floating gate, a dielectric layer and a control gate, and dielectric layer contact holes respectively formed in the dielectric layers between the control gates and the floating gates of the select lines. The floating gates and the control gates are connected in regions where the dielectric layer contact holes are formed.

In another aspect, a method of forming a semiconductor device includes forming a first conductive layer over a semiconductor substrate. A dielectric layer is formed over the first conductive layer. A mask pattern having a first opening is formed over the dielectric layer. The mask pattern is annealed to convert the first opening into a second opening that is smaller than the first opening. The dielectric layer is etched using the mask pattern with the second opening to form a hole that exposes the first conductive layer. A second conductive layer is formed over the dielectric layer and within the hole, the second conductive layer contacting the first conductive layer pattern through the hole.

### BRIEF DESCRIPTION OF THE DRAWINGS

FIGS. 1A to 1F are layout diagrams illustrating a flash memory device according to the present invention;

FIGS. 2A to 2F are cross-sectional views along plane A-A′ in FIGS. 1A to 1F illustrating a method of manufacturing a flash memory device according to the present invention;

FIG. 3 is a photograph showing variation in the photoresist pattern of a line shape depending on the resist flow process; and

FIG. 4 is a photograph showing variation in the photoresist pattern of a hole shape depending on the resist flow process.

### DESCRIPTION OF SPECIFIC EMBODIMENTS

A specific embodiment according to the present patent will be described with reference to the accompanying drawings.

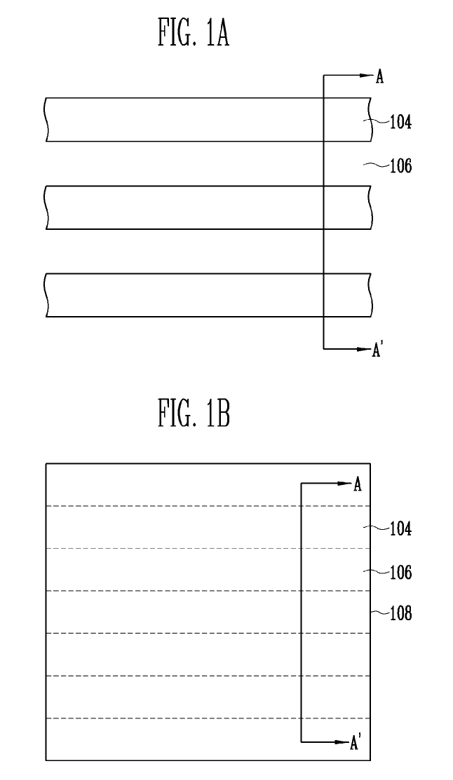

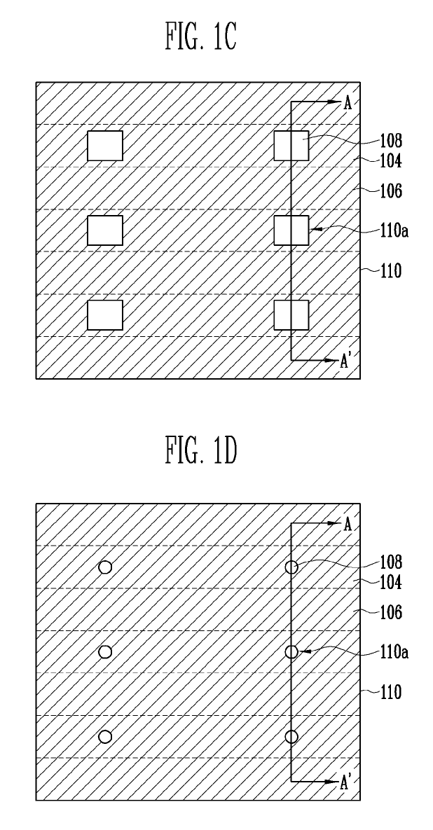

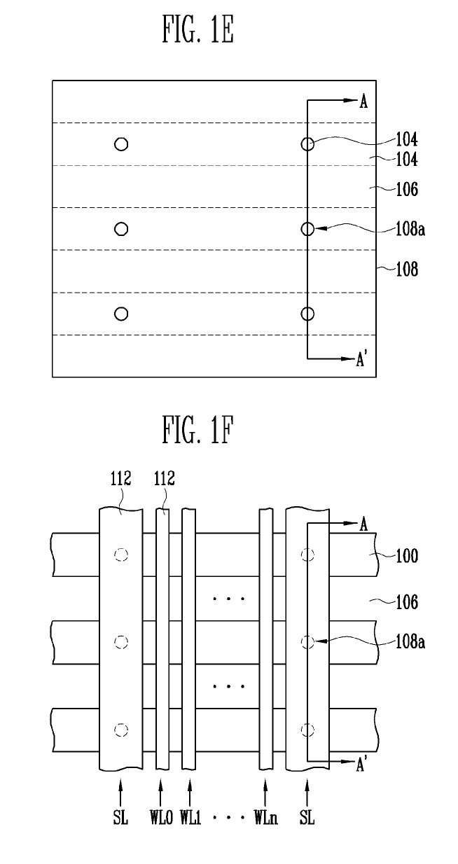

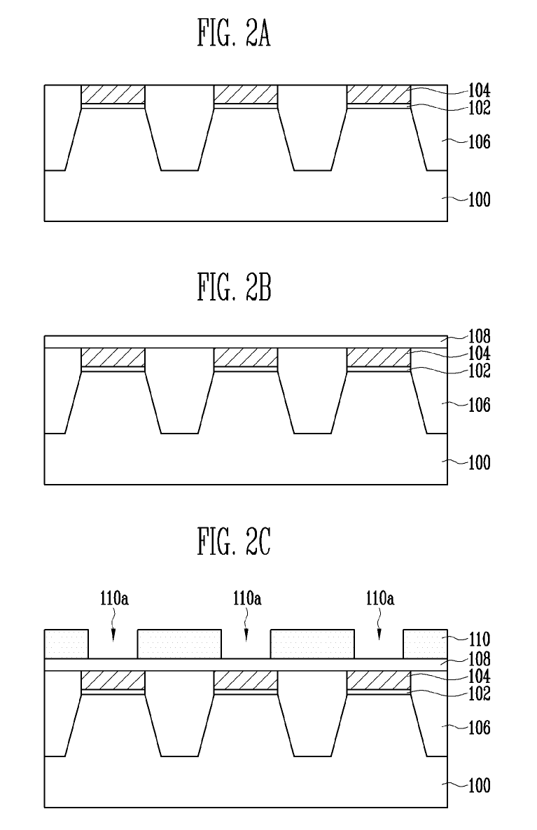

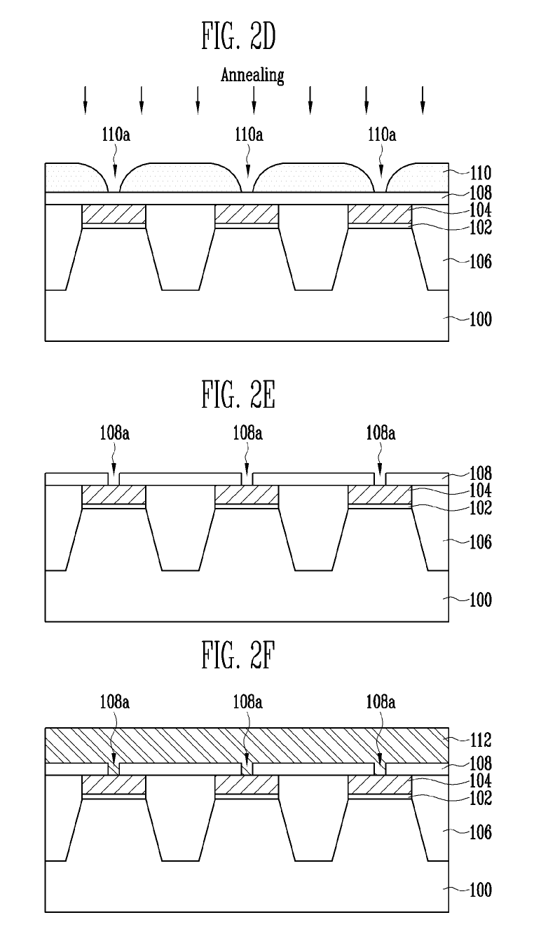

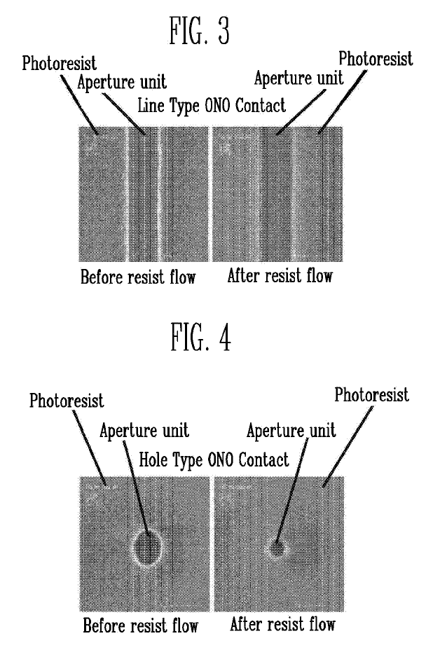

FIGS. 1A to 1F are layout diagrams illustrating a flash memory device according to the present invention. FIGS. 2A to 2F are cross-sectional views along plane A-A′ in FIGS. 1A to 1F illustrating a method of manufacturing a flash memory device according to the present invention.

Referring to FIGS. 1A and 2A, a trench-shaped isolation layer 106 is formed in an isolation region of a semiconductor substrate 100, and a tunnel insulating layer 102 and a first conductive layer 104 for a floating gate are formed in an active region. A formation method of the elements is described below in detail.

The tunnel insulating layer 102 and the first conductive layer 104 are formed over the semiconductor substrate 100. An isolation mask (not illustrated) is formed on the first conductive layer 104. The first conductive layer 104 and the tunnel insulating layer 102 are patterned along the isolation mask, and part of the semiconductor substrate 100 is removed to form trenches. An insulating layer (i.e., isolation layer 106) is formed so that the trenches are fully filled. A chemical mechanical polishing (CMP) process is performed so that the first conductive layer 104 is exposed, thereby removing part of the isolation layer 106 and the isolation mask. A conductive layer for a floating gate whose edges are overlapped with the isolation layer 106 can be further formed on the first conductive layer 104 in order to increase the area of the floating gate.

Referring to FIGS. 1B and 2B, a dielectric layer 108 is formed on the semiconductor substrate 100 so that both the first conductive layer 104 and the isolation layer 106 are covered. The dielectric layer 108 isolates the floating gate and the control gate in the memory cell so that a charge stored in the floating gate can be maintained.

Meanwhile, in a string structure of a NAND flash memory device, select transistors formed at both ends of the string structure must perform the function of a general transistor and not a data storage cell. Thus, part of the dielectric layer for the select transistors must be opened so that an electrical path can be made between conductive layers for the floating gate and the control gate. To this end, a method of forming a dielectric layer contact hole in a section of the dielectric layer 108 is described below.

Referring to FIGS. 1C and 2C, a photoresist pattern 110 having aperture units 110a through which the dielectric layer contact holes is formed in the dielectric layer 108. The aperture units 110a are formed in the photoresist by performing exposure and development processes employing an exposure apparatus. The aperture units 110a are located within the regions of the first conductive layer (104) pattern. However, as the degree of integration of semiconductor devices is increased and the line width of the device is reduced, it is difficult to form aperture units with narrow openings by using the existing exposure equipment. This existing equipment tend to have low resolution in comparison with the degree of integration. Thus, at the time of the exposure and development process, the shortage of overlay margin with respect to the aperture units may occur. Due to this, device failure may occur.

As the degree of integration of devices increases, an exposure apparatus having high resolution compared with the existing apparatus can be used. It requires an expensive apparatus, leading to an increased manufacturing cost including the installation cost.

In the present embodiment, the aperture units 110a are formed by using the existing exposure equipment, wherein the size of the aperture units is reduced by means of a subsequent process so that the aperture units can be formed within the desired regions having a desired size.

Referring to FIGS. 1D and 2D, the size of the aperture units 110a formed in the photoresist pattern 110 is reduced by performing a resist flow process. The resist flow process refers to annealing of the photoresist pattern. When annealing is performed, the size of the aperture units 110a is reduced as part of the photoresist flows into the aperture units 110a by reducing the viscosity of the photoresist pattern 110a. The resist flow process can be implemented under a general atmosphere at a temperature ranging from 135 to 150 degrees Celsius for 60 to 90 seconds.

If the resist flow process is carried out, the shape of the aperture units 110a changes to a circular shape (or round shape) and the size of the aperture units 110a decreases. Thus, alignment margin can be secured within the first conductive layer (104) pattern region.

For convenience of description the drawings of the present invention show only one aperture unit for each transistor. However, the pattern can be formed to have a plurality of aperture units with different sizes.

Referring to FIGS. 1E and 2E, in order form dielectric layer contact holes 108a in the dielectric layer 108, an etch process is performed along the photoresist pattern (refer to 110 in FIG. 2D). The etch process is performed until part of the first conductive layer 104 is exposed so that a subsequent control gate is brought in contact with the first conductive layer 104. The photoresist pattern (refer to 110 in FIG. 2D) is then removed. The dielectric layer contact holes 108a are formed using the photoresist pattern, so that sufficient alignment margin can be secured within the first conductive layer (104) region.

In particular, it has been shown that the dielectric layer contact holes 108a are formed in a line fashion parallel to the direction of the word line. However, in order to perform a resist flow process, the dielectric layer contact holes 108a can be formed in hole form in transistor regions that will be subsequently formed.

The following is based on experiments conducted by the inventor. The aperture units of the line form, which are formed along the word line direction as illustrated in FIG. 3, have their widths rarely changed or have their widths partially widened although the resist flow process is performed. In the case of an aperture unit formed in hole form as shown in FIG. 4, it can be seen that the size of the aperture unit is significantly reduced after the resist flow process is performed. It can also be seen that although the hole of the aperture unit is formed in an elliptical shape or a square shape before the resist flow process is performed, the shape of the aperture unit is changed to a circular shape after the resist flow process is carried out. Accordingly, the dielectric layer contact holes 108a are formed in hole form in the transistors and can be formed with sufficient alignment margin within the region of the first conductive layer 104.

Referring to FIGS. 1F and 2F, a second conductive layer 112 for a control gate is formed on the dielectric layer 108 and the partially exposed first conductive layer (104) pattern. The second conductive layer 112 is formed within the contact holes (or openings) 108a to contact the first conductive layer (104) pattern. The second conductive layer 112, the dielectric layer 108 and the first conductive layer 104 are patterned to form select lines SL and word lines WL0 to WLn. Part of the select lines SL becomes source select lines, and the remaining select lines become drain select lines. In the select line SL, each of the dielectric layer contact holes 108a is formed between the first conductive layer 104 and the second conductive layer 112, but is not formed in the region where the isolation layer is formed. Accordingly, in the select line SL, the first conductive layer 104 and the second conductive layer 112 are connected through the dielectric layer contact hole 108a, thereby forming a select transistor.

As described above, according to the present invention, the aperture units are formed on a photo resist layer and then an annealing process is carried out to reduce the size of the aperture units. This enables the formation of smaller holes or openings without using a new exposure equipment with finer resolution capability. A photoresist pattern having a small size provides an increased etch margin for the dielectric layer contact holes, and an etch process for forming the dielectric layer contact holes can be implemented more easily.

Although the foregoing description has been made with reference to the specific embodiment, it is to be understood that changes and modifications of the present patent may be made by the ordinary skilled in the art without departing from the spirit and scope of the present patent and appended claims.

What is claimed is:

1. A method of forming a semiconductor device, the method comprising:
forming a first conductive layer pattern and an isolation layer over a semiconductor substrate;
forming a dielectric layer over the isolation layer and the first conductive layer;
forming a mask pattern having first aperture units on the dielectric layer;
performing an annealing process to convert the first aperture units into second aperture units that have smaller openings than the first aperture units;
patterning the dielectric layer using the mask pattern with the second aperture units to form holes that expose the first conductive layer pattern; and
forming a second conductive layer over the dielectric layer and within the holes, the second conductive layer contacting the first conductive layer pattern through the holes.

2. The method of claim 1, further comprising:
before forming the isolation layer, forming a tunnel insulating layer, a first conductive layer and an isolation mask pattern over the semiconductor substrate;
performing an etch process using the isolation mask pattern to form the first conductive layer pattern, a tunnel insulating layer pattern and trenches;
forming an isolation insulating layer to fill the trenches; and
performing a chemical mechanical polishing process to expose part of the first conductive layer.

3. The method of claim 1, wherein the annealing is performed at a temperature ranging from 135 to 150 Celsius degrees for 60 to 90 seconds.

4. The method of claim 1, wherein:
the first aperture units have a circular, elliptical or square shape, and the second aperture units have substantially a circular shape after the annealing process.

5. The method of claim 1, wherein the number of the first aperture units is at least one.

6. The method of claim 1, further comprising:
removing the mask pattern prior to forming the second conductive layer.

7. The method of claim 6, wherein the mask pattern is made of photoresist.

8. The method of claim 1, wherein the device is a flash memory device.

9. A method of forming a semiconductor device, the method comprising:
forming a first conductive layer over a semiconductor substrate;
forming a dielectric layer over the first conductive layer;
forming a mask pattern having a first opening over the dielectric layer;
annealing the mask pattern to convert the first opening into a second opening that is smaller than the first opening;
etching the dielectric layer using the mask pattern with the second opening to form a hole that exposes the first conductive layer; and
forming a second conductive layer over the dielectric layer and within the hole, the second conductive layer contacting the first conductive layer pattern through the hole.

10. The method of claim 9, wherein the mask pattern is made of photoresist.

11. A flash memory device, comprising:
an isolation layer formed in an isolation region of a semiconductor substrate;
a plurality of word lines and select lines formed over the semiconductor substrate and crossing the isolation layer, each of the plurality of word lines and select lines including a floating gate, a dielectric layer and a control gate; and
dielectric layer contact holes respectively formed in the dielectric layers between the control gates and the floating gates of the select lines,
wherein the floating gates and the control gates are connected in regions where the dielectric layer contact holes are formed.
